(19) United States
(12) Patent Application Publication
(10) Pub. No.: US 2026/0013126 A1
(43) Pub. Date: Jan. 8, 2026

(54) MEMORY DEVICE AND METHOD OF FORMING THE SAME

(71) Applicant: YANGTZE MEMORY TECHNOLOGIES CO., LTD., Wuhan (CN)

(72) Inventors: Zhaosong Li, Wuhan (CN); Jianlan Wei, Wuhan (CN); Liyuan Zhang, Wuhan (CN); Sizhe Li, Wuhan (CN); Xiaoming Mao, Wuhan (CN); Jing Gao, Wuhan (CN); Yi Tang, Wuhan (CN); Zhiguo Wang, Wuhan (CN); Zongliang Huo, Wuhan (CN)

(21) Appl. No.: 18/790,582

(22) Filed: Jul. 31, 2024

Related U.S. Application Data
(63) Continuation of application No. PCT/CN2024/103041, filed on Jul. 2, 2024.

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

A memory device includes a stack structure including a plurality of gate lines and a select gate line, a first channel structure extending through the plurality of gate lines along a first direction, a dielectric layer disposed on the first channel structure and the select gate line, and extending along a second direction perpendicular to the first direction, and a conductive layer disposed in the dielectric layer, and the conductive layer in contact with the select gate line.

### CROSS-REFERENCE TO RELATED APPLICATIONS

This application is a continuation of International Application No. PCT/CN2024/103041, filed on Jul. 2, 2024, which is hereby incorporated by reference in its entirety.

### BACKGROUND

The present disclosure relates to memory devices, and specifically, relates to an improved structure of the memory devices and method of forming the memory devices.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

According to one aspect of the present disclosure, a memory device is disclosed. The memory device includes a stack structure including a plurality of gate lines and a select gate line, a first channel structure extending through the plurality of gate lines along a first direction, a dielectric layer disposed on the first channel structure and the select gate line, and extending along a second direction perpendicular to the first direction, and a conductive layer disposed in the dielectric layer, and the conductive layer in contact with the select gate line.

In some implementations, a top portion of the first channel structure is filled with the dielectric layer.

In some implementations, a first bottom surface of the dielectric layer is lower than a second bottom surface of the select gate line in a side view of the memory device.

In some implementations, the first channel structure includes a blocking layer, a storage layer, a tunneling layer, a semiconductor channel layer, and a capping layer stacking along the second direction, and a first top surface of the semiconductor channel layer is lower than the second bottom surface of the select gate line in the side view of the memory device.

In some implementations, the dielectric layer covers at least one first channel structure.

In some implementations, the memory device further includes an isolation structure dividing the select gate line into a plurality of sections.

In some implementations, the isolation structure extends along the first direction and a third direction perpendicular to the first direction and the second direction.

In some implementations, the isolation structure is disposed in the dielectric layer.

In some implementations, the isolation structure is disposed between the first channel structure and an adjacent channel structure.

In some implementations, the first channel structure or the adjacent channel structure includes a blocking layer, a storage layer, a tunneling layer, a semiconductor channel layer, and a capping layer stacking along the second direction, and a portion of the storage layer of the first channel structure or the adjacent channel structure is covered by the isolation structure.

In some implementations, a second top surface of the portion of the storage layer covered by the isolation structure is lower than the select gate line in a side view of the memory device.

In some implementations, a first thickness of the select gate line is greater than a second thickness of each of the plurality of gate lines.

In some implementations, the select gate line is formed by a semiconductor material.

In some implementations, the memory device includes a core region and a pick-up region. A plurality of first channel structures, the dielectric layer, and the conductive layer are disposed in the pick-up region, and a plurality of second channel structures are disposed in the core region.

In some implementations, a first arrangement of the plurality of first channel structures in the pick-up region in a plan view of the memory device is the same as a second arrangement of the plurality of second channel structures in the core region in the plan view of the memory device.

According to another aspect of the present disclosure, a memory device is disclosed. The memory device includes a stack structure including a plurality of gate lines and a select gate line, and a channel structure extending through the plurality of gate lines along a first direction. The channel structure includes a semiconductor channel and a memory film disposed over the semiconductor channel, and a first top surface of the semiconductor channel is lower than a second top surface of the select gate line in a side view of the memory device.

In some implementations, the memory film includes a tunneling layer over the semiconductor channel, a storage layer over the tunneling layer, and a blocking layer over the storage layer, and the first top surface of the semiconductor channel is lower than a third top surface of the memory film in the side view of the memory device.

In some implementations, the first top surface of the semiconductor channel is lower than a bottom surface of the select gate line in the side view of the memory device.

In some implementations, the memory device further includes a dielectric layer disposed on the channel structure and the select gate line, and extending along a second direction perpendicular to the first direction, and a conductive layer disposed in the dielectric layer, and the conductive layer in contact with the select gate line.

In some implementations, a first thickness of the dielectric layer is greater than a second thickness of the select gate line.

In some implementations, a top portion of the channel structure includes the dielectric layer surrounded by the memory film.

According to a further aspect of the present disclosure, a method of forming a memory device is disclosed. The method includes forming a stack structure and a select gate line on the stack structure, forming a channel structure extending in the stack structure along a first direction, dividing the select gate line into a plurality of sections, removing a top portion of the channel structure, forming a first dielectric layer on the top portion of the channel structure, and forming a conductive layer in the first dielectric layer in contact with the select gate line.

In some implementations, forming the channel structure extending in the stack structure along the first direction includes forming a channel hole extending in the stack structure along the first direction, forming a memory film in the channel hole, and forming a semiconductor channel over the memory film in the channel hole.

In some implementations, dividing the select gate line into the plurality of sections includes forming a trench dividing the select gate line into the plurality of sections, and forming a second dielectric layer in the trench to isolate the plurality of sections.

In some implementations, removing the top portion of the channel structure includes removing the second dielectric layer and a portion of the semiconductor channel.

In some implementations, the semiconductor channel includes a first polysilicon layer and the select gate line includes a second polysilicon layer, and the first polysilicon layer and the second polysilicon layer have different etching rates in a removal operation.

In some implementations, a first etching rate of the first polysilicon layer is greater than a second etching rate of the second polysilicon layer in the removal operation.

In some implementations, forming the first dielectric layer on the top portion of the channel structure includes forming the first dielectric layer covering the semiconductor channel and the select gate line.

### BRIEF DESCRIPTION OF THE DRAWINGS

The accompanying drawings, which are incorporated herein and form a part of the specification, illustrate implementations of the present disclosure and, together with the description, further serve to explain the present disclosure and to enable a person skilled in the pertinent art to make and use the present disclosure.

FIG. 1 illustrates a plan view of an exemplary memory device, according to some implementations of the present disclosure.

FIGS. 2A-2B illustrate cross-sections of an exemplary memory device, according to some implementations of the present disclosure.

FIGS. 3-13 illustrate cross-sections of an exemplary memory device at different stages of a manufacturing process, according to some implementations of the present disclosure.

FIG. 14 illustrates a flowchart of an exemplary method for forming a memory device, according to some implementations of the present disclosure.

FIG. 15 illustrates a block diagram of an exemplary system having a memory device, according to some implementations of the present disclosure.

FIG. 16A illustrates a diagram of an exemplary memory card having a memory device, according to some implementations of the present disclosure.

FIG. 16B illustrates a diagram of an exemplary solid-state drive (SSD) having a memory device, according to some implementations of the present disclosure.

Implementations of the present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “3D memory device” refers to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means perpendicular to the lateral surface of a substrate.

In some 3D memory devices, such as 3D NAND memory devices, a stack of gate electrodes may be arranged over a substrate, with a plurality of semiconductor channels through and intersecting word lines into the implanted substrate. The bottom/lower gate electrodes or electrodes function as source select gate lines, which are also called bottom select gates (BSG) in some cases. The top/upper gate electrodes or electrodes function as drain select gate (DSG) lines, which are also called top select gates (TSG) in some cases. The gate electrodes between the top/upper select gate electrodes and the bottom/lower gate electrodes function as word lines (WLs). The intersection of a word line and a semiconductor channel forms a memory cell.

As the demand for higher memory capacity continues, 3D NAND memory devices with multi-deck structures have been proposed. Compared to existing 3D NAND memory devices, 3D NAND memory devices with multi-deck structures often have more levels (or conductor/dielectric layer pairs or stairs) along the vertical direction. When the total thickness of the dielectric layer, including silicon oxide and/or silicon nitride, increases, the etching operation becomes more difficult. At the same time, the TSG poly silicon layer requires multiple sets of pick-ups to be connected, and the multiple pick-ups need to be placed next to the effective channels to reduce the resistance and lead out the TSG. The difficulty of the channel etching process further increases.

To address the aforementioned issues, the present disclosure introduces improved structures of the memory devices and methods of forming the memory devices, in which the channel structures in the pick-up region and the core region are the same to reduce the etching difficulty. At the same time, the present disclosure also forms the TSG pick-up by performing the photolithography, etching, and deposition operations after forming the channels to realize the TSG pick-up design.

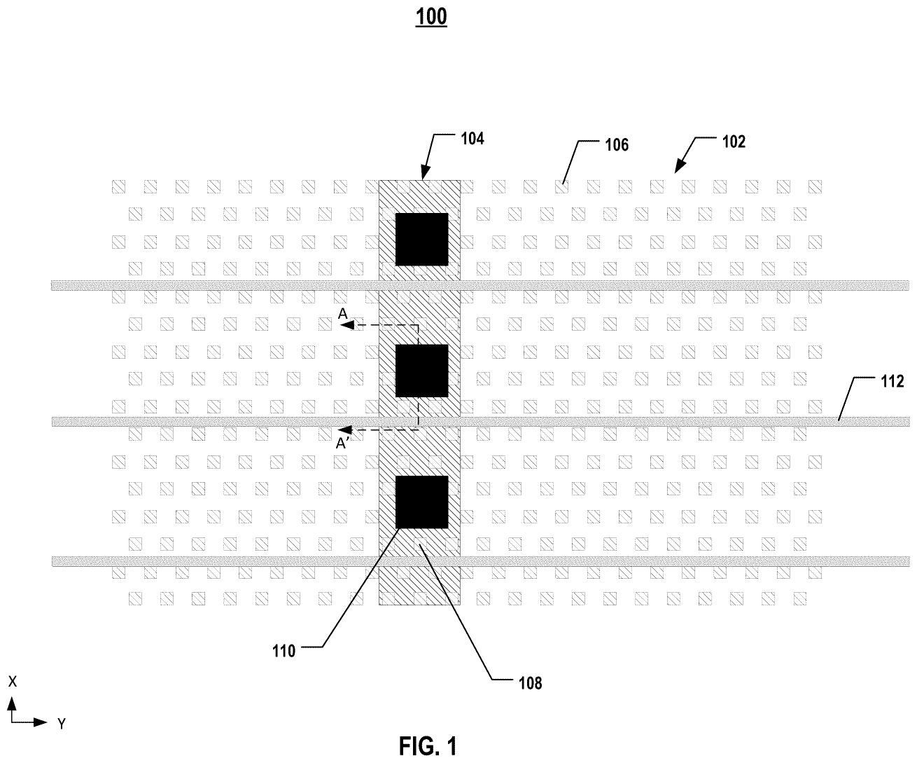

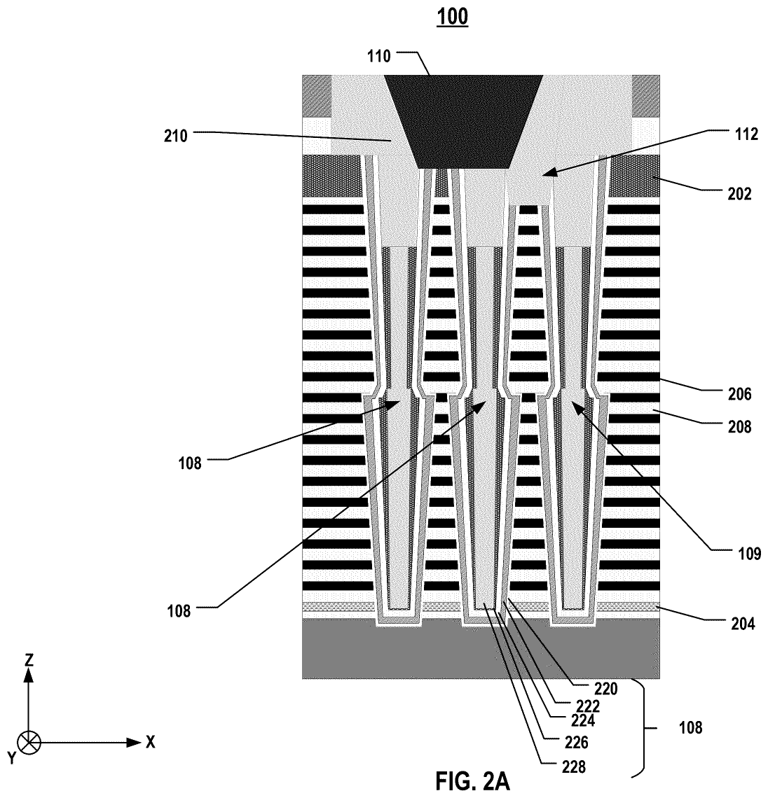

FIG. 1 illustrates a plan view of a memory device 100, according to some implementations of the present disclosure. FIGS. 2A-2B illustrate cross-sections of the memory device 100 along line AA′ in FIG. 1, according to some implementations of the present disclosure. As shown in FIG. 1, the memory device includes a core region 102 and a pick-up region 104. A plurality of first channel structures 108 are formed in the pick-up region 104, and a plurality of second channel structures 106 are formed in the core region 102. In some implementations, the arrangement of the plurality of first channel structures 108 in the pick-up region 104 in a plan view of the memory device 100 is the same as the arrangement of the plurality of second channel structures 106 in the core region 102 in the plan view of the memory device. In other words, the channel structures in both core region 102 and pick-up region 104 can be designed the same to reduce the etching difficulty. Furthermore, the manufacturing process can also be simplified for the channel structures in both the core region 102 and the pick-up region 104.

As shown in FIG. 2A, memory device 100 includes a stack structure formed by a plurality of gate lines 206, a select gate line 202, e.g., one or more top select gates (TSGs), and one or more bottom select gates (BSGs) 204. In some implementations, gate lines 206 may include conductive layers or dielectric layers depending on performing the gate replacement operations. In some implementations, before the gate replacement operation, the stack structure may include interleaved dielectric layers. For example, the stack structure may include interleaved silicon nitride layers and silicon oxide layers. In some implementations, after the gate replacement operation, the stack structure may include interleaved conductive layers and dielectric layers extending in the X-direction. In some implementations, conductive layers may be the word lines, and dielectric layer 208 may be the silicon oxide layers. In some implementations, the conductive layer may be a gate structure including a gate conductive layer and a gate dielectric layer formed between the gate conductive layer and the dielectric layer 208. In some implementations, the gate dielectric layer may include any suitable dielectric materials, such as silicon oxide, silicon nitride, silicon oxynitride, or high-k dielectrics. In some implementations, the gate dielectric layer includes silicon oxide, which is a form of a gate oxide. The gate conductive layer may include any suitable conductive materials, such as polysilicon, metals (e.g., W, Cu, Al, etc.), metal compounds (e.g., TiN, TaN, etc.), or silicides. In some implementations, the gate conductive layer may include doped polysilicon, which is a form of a gate poly.

As shown in FIG. 2A, the first channel structure 108 extends along the Z-direction through the plurality of gate lines 206. The select gate line 202 is formed above the stack structure. A dielectric layer 210 is formed on the first channel structure 108 and the select gate line 202 extending along the X-direction. A conductive layer 110, e.g., a pick-up structure, is formed in the dielectric layer 210, and the conductive layer 110 is in contact with the select gate line 202. In other words, the conductive layer 110 is formed in the dielectric layer 210 and in contact with the select gate line 202 to achieve the TSG pick-up function.

In some implementations, an isolation structure 112, e.g., the TSG cut structure, may be formed in the dielectric layer 210 dividing the select gate line 202 into a plurality of sections. In some implementations, the isolation structure 112 extends along the Z-direction and the Y-direction to divide the select gate line 202 into a plurality of sections. In some implementations, the dielectric layer 210 and the isolation structure 112 may be formed by the same material, e.g., silicon oxide, silicon nitride, or silicon oxynitride. In some implementations, the boundary between the dielectric layer 210 and the isolation structure 112 may not be obvious in the cross-sectional view, as shown in FIG. 2A.

As shown in FIG. 2A, the first channel structure 108 includes a blocking layer 220, a storage layer 222, a tunneling layer 224, a semiconductor channel layer 226, and a capping layer 228 stacking along the X-direction. In some implementations, the first channel structure 108 includes the blocking layer 220, the storage layer 222, the tunneling layer 224, the semiconductor channel layer 226, and the capping layer 228 stacking along the radial direction of the channel structure 108. In some implementations, the blocking layer 220, the storage layer 222, and the tunneling layer 224 are also named as a memory film. In some implementations, the semiconductor channel layer 226, and the capping layer 228 are also named as a semiconductor channel. In some implementations, the blocking layer 220 may include silicon oxide, silicon oxynitride, high dielectric material, or any combination thereof. In some implementations, the storage layer 222 may include silicon nitride, silicon oxynitride, silicon, or any combination thereof. In some implementations, the tunneling layer 224 may include silicon oxide, silicon oxynitride, or any combination thereof. In some implementations, the memory film may be a composite layer of silicon oxide/silicon nitride/silicon oxide (ONO).

As shown in FIG. 2A, a top portion of the first channel structure 108 is filled with the dielectric layer 210. Specifically, the memory film, including the blocking layer 220, the storage layer 222, and the tunneling layer 224, is higher than the semiconductor channel, including the semiconductor channel layer 226 and the capping layer 228, and the space formed between the memory film and the semiconductor channel is filled with the dielectric layer 210. In other words, a top portion of channel structure 108 includes the dielectric layer 210 surrounded by the memory film.

In some implementations, a first bottom surface of the dielectric layer 210 is lower than a second bottom surface of the select gate line 202 in a side view of the memory device 100. In some implementations, a first top surface of the semiconductor channel, including the semiconductor channel layer 226 and the capping layer 228, is lower than the second bottom surface of the select gate line 202 in the side view of the memory device 100.

In some implementations, the dielectric layer 210 covers at least one first channel structure 108. In some implementations, the isolation structure 112 is disposed between the first channel structure 108 and an adjacent channel structure 109. In some implementations, as shown in FIG. 2A, a portion of the storage layer 222 of the first channel structure 108 or the adjacent channel structure 109 is covered by the isolation structure 112. In some implementations, as shown in FIG. 2B, the isolation structure 112 may cut only one channel structure, e.g., the adjacent channel structure 109, and a portion of the blocking layer 220, the storage layer 222, and the tunneling layer 224 of the adjacent channel structure 109 is covered by the isolation structure 112. In some implementations, the isolation structure 112 may also cover the semiconductor channel layer 226. In some implementations, a second top surface of the portion of the storage layer 222 covered by the isolation structure 112 is lower than the select gate line 202 in a side view of the memory device 100. In some implementations, a first thickness of the select gate line 202 is greater than a second thickness of each of the plurality of gate lines 206. In some implementations, the select gate line 202 is formed by a semiconductor material. In some implementations, the thickness of the dielectric layer 210 is greater than the thickness of the select gate line 202.

It is noted that, in some implementations, after the channel structures are formed, the memory device 100 may be flipped over and the substrate may be removed to expose the channel structures. Then, the blocking layer 220, the storage layer 222, and the tunneling layer 224 may be removed to expose the semiconductor channel layer 226. A semiconductor layer, e.g., a polysilicon layer, may be formed on the exposed semiconductor channel layer 226 to be a common source.

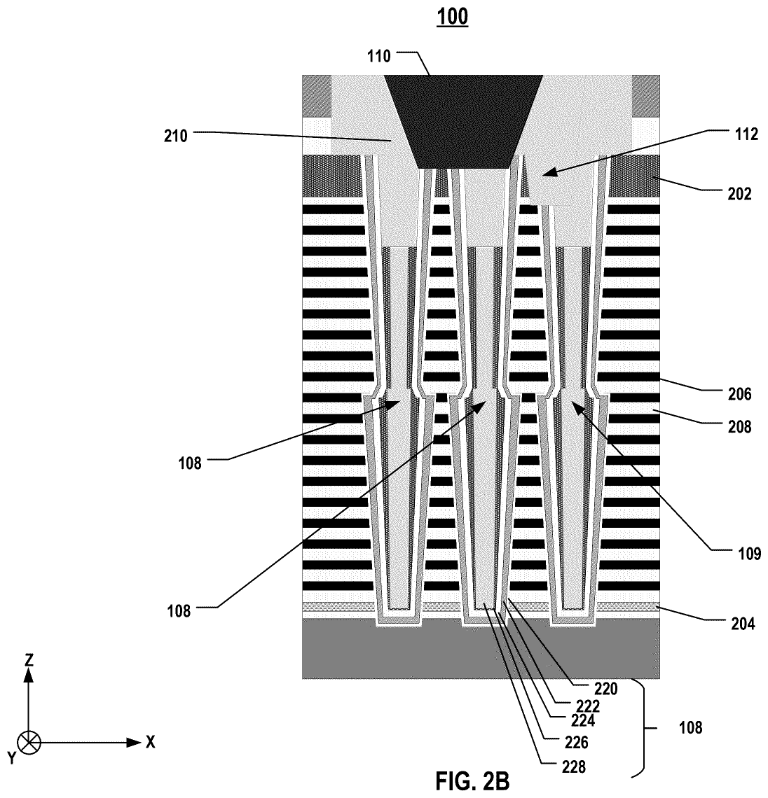

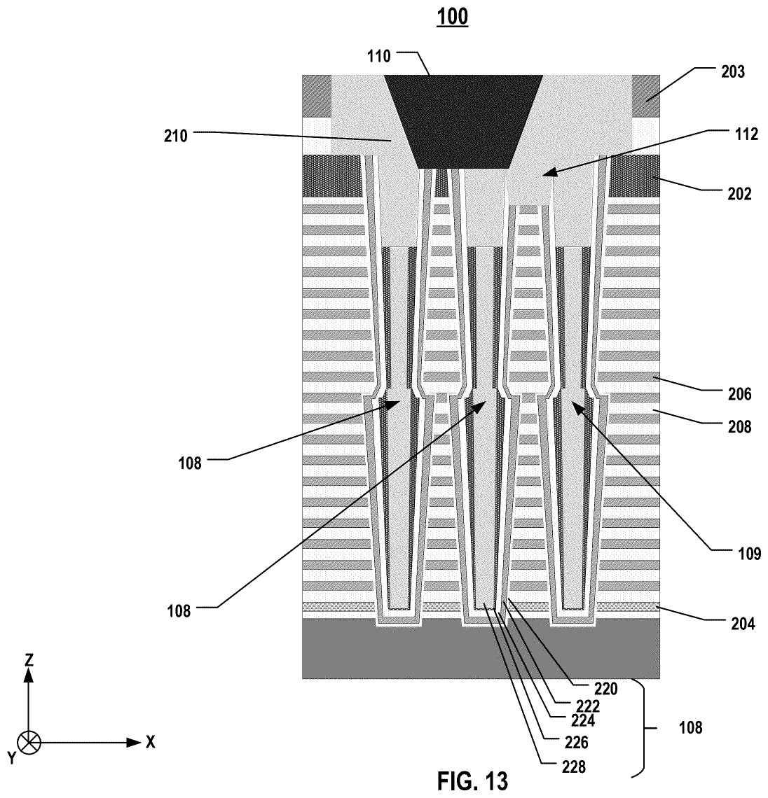

FIGS. 3-13 illustrate cross sections of the memory device 100 at different stages of a manufacturing process, according to some implementations of the present disclosure. FIG. 14 illustrates a flowchart of an exemplary method 1400 for forming the memory device 100, according to some implementations of the present disclosure. For the purpose of better describing the present disclosure, the cross-sections of the memory device 100 in FIGS. 3-13 and the method 1400 in FIG. 14 will be described together. It is understood that the operations shown in method 1400 are not exhaustive and that other operations may be performed as well before, after, or between any of the illustrated operations. Further, some of the operations may be performed simultaneously, or in a different order than shown in FIGS. 3-13 and FIG. 14.

As shown in FIG. 3 and operation 1402 in FIG. 14, a stack structure is formed. The stack structure includes interleaved gate lines 206 and dielectric layers 208 extending in the X-direction on a substrate. In some implementations, a BSG 204 may be formed between the stack structure and the substrate. It is noted here, in some implementations, the stack structure may include interleaved dielectric layers, e.g., interleaved silicon oxide layers and silicon nitride layers, and the word line replacement operation may be performed later to replace the silicon nitride layers with conductive layers.

In some implementations, gate line 206 may be the word lines, and the dielectric layer 208 may be the silicon oxide layers. In some implementations, gate line 206 may be dielectric layers, e.g., the silicon nitride layers, and the dielectric layer 208 may be the silicon oxide layers. In some implementations, when gate line 206 is the dielectric layer, e.g., the silicon nitride layer, the silicon nitride layer may be replaced by a conductive layer after performing a replacement operation in a later procedure. In some implementations, gate line 206 may be a gate structure including a gate dielectric layer and a gate conductive layer on gate dielectric layer. In some implementations, the gate dielectric layer may include any suitable dielectric materials, such as silicon oxide, silicon nitride, silicon oxynitride, or high-k dielectrics. In some implementations, the gate dielectric layer includes silicon oxide, which is a form of a gate oxide. The gate conductive layer may include any suitable conductive materials, such as polysilicon, metals (e.g., W, Cu, Al, etc.), metal compounds (e.g., TiN, TaN, etc.), or silicides. In some implementations, the gate conductive layer may include doped polysilicon, which is a form of a gate poly. The select gate line 202 is formed on the stack structure.

In some implementations, the BSG 204, the select gate line 202, and the stack structure are formed together. The bottom/lower gate electrode or electrodes function as source select gate (SSG) lines, which are also called bottom select gates (BSG) in some cases. The top/upper gate electrode or electrodes function as drain select gate (DSG) lines, which are also called top select gates (TSG) in some cases.

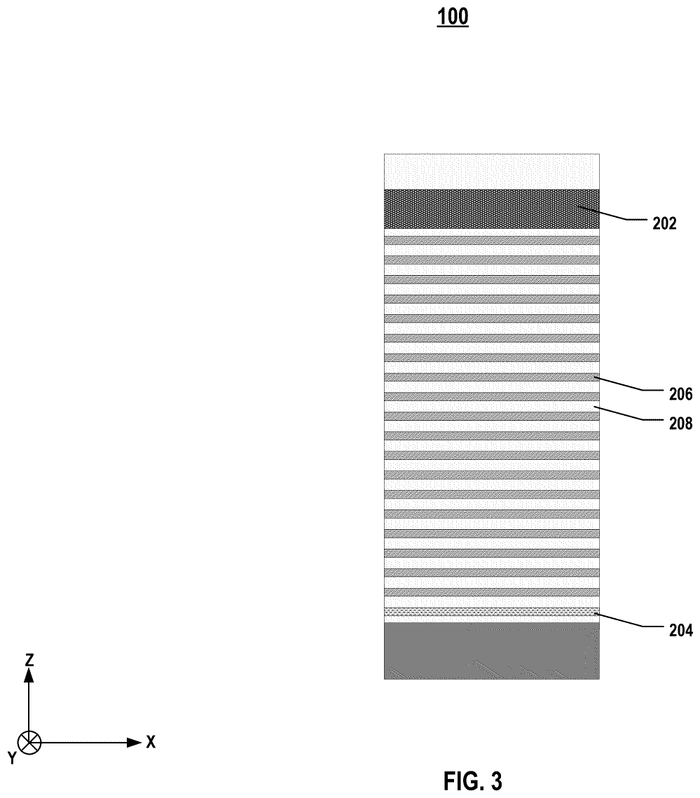

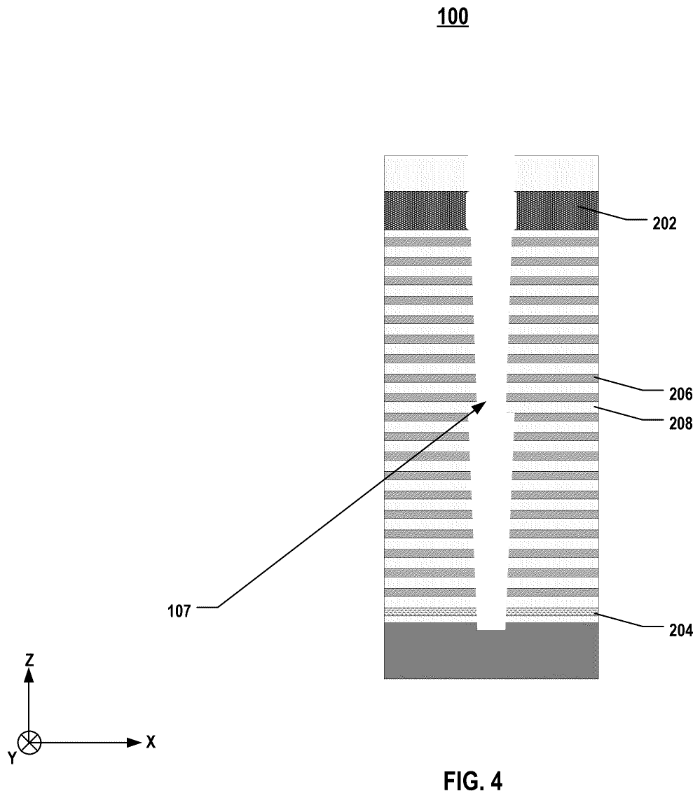

As shown in FIGS. 4-5 and operation 1404 in FIG. 14, a channel structure 108 is formed extending in the stack structure along the Z-direction. As shown in FIG. 4, a channel hole 107 is formed, extending in the stack structure along the Z-direction. Then, as shown in FIG. 5, a memory film, including the blocking layer 220, the storage layer 222, and the tunneling layer 224, is formed in the channel hole. Then, a semiconductor channel, including semiconductor channel layer 226 and the capping layer 228, is formed over the memory film in the channel hole.

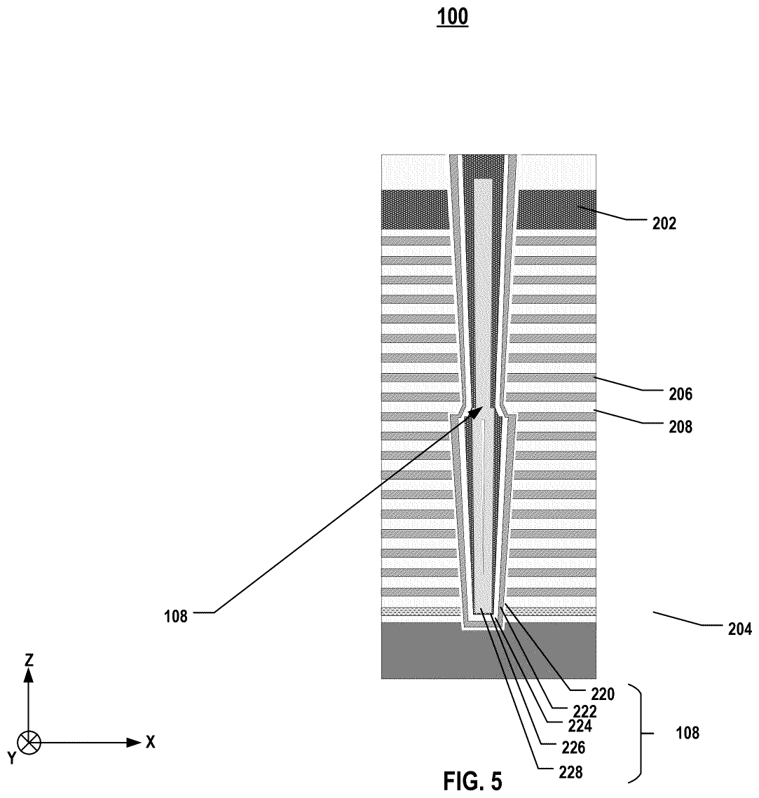

As shown in FIG. 6 and operation 1406 in FIG. 14, the select gate line 202 is divided into a plurality of sections by a trench structure 111. In some implementations, a sacrificial layer 203 is formed on the select gate line 202, and the trench structure 111 is formed extending into the sacrificial layer 203, the select gate line 202, and a portion of the channel structure 108 along the Z-direction and the Y-direction. In some implementations, the location of the trench structure 111 is the location of the later-formed isolation structure 112, e.g., the TSG cut structure.

In some implementations, a trench is formed extending into the sacrificial layer 203, the select gate line 202, and a portion of the channel structure 108 along the Z-direction and the Y-direction to divide the select gate line 202 into the plurality of sections. Then, the trench structure 111, e.g., a dielectric layer, is formed in the trench to isolate the plurality of sections.

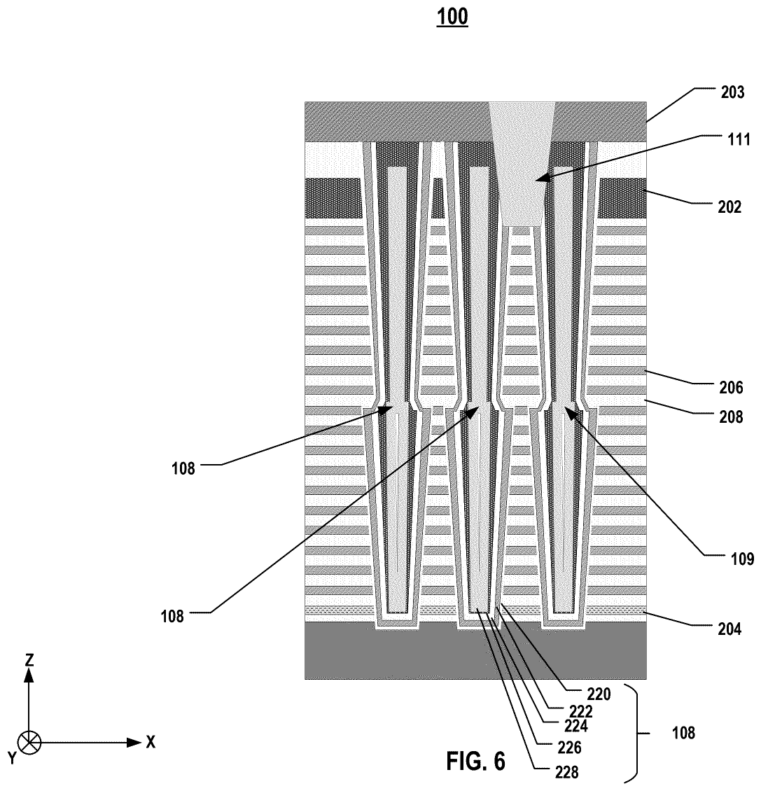

As shown in FIGS. 7-11 and operation 1408 in FIG. 14, a top portion of the channel structure 108 is removed. As shown in FIG. 7, a masking layer 205, e.g., a photoresistor layer, is formed on the sacrificial layer 203 to define the TSG pick-up area. In some implementations, the opening in masking layer 205 defines the pick-up region 104 shown in FIG. 1. In some implementations, the pick-up region 104 covers a plurality of channel structures, including the first channel structure 108 and the adjacent channel structure 109.

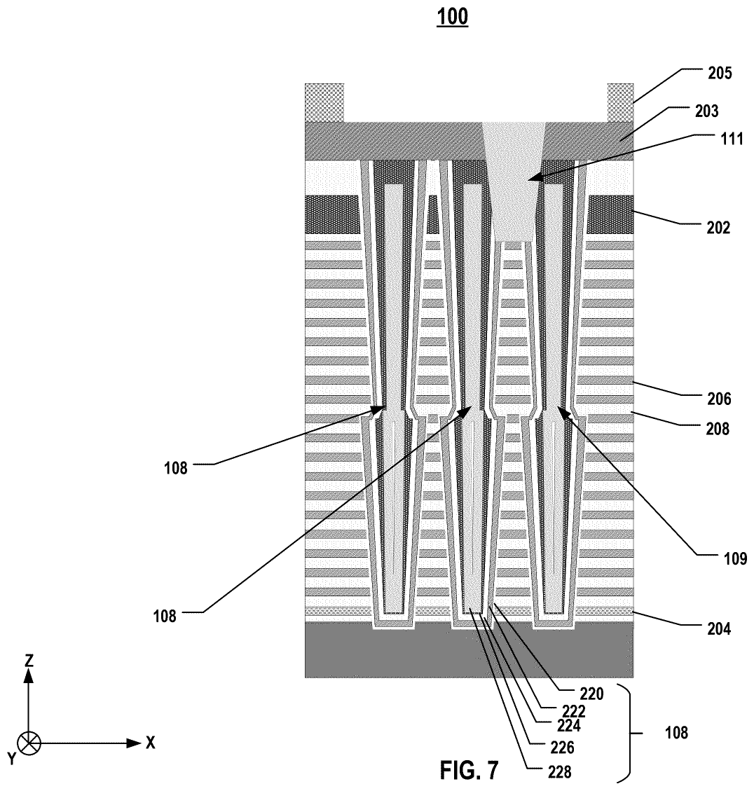

Then, as shown in FIG. 8, a first removal operation, e.g., a dry etching process or a wet etching process, is performed to remove a portion of the sacrificial layer 203. In some implementations, the sacrificial layer 203 may include silicon oxide, silicon nitride, or silicon oxynitride. In some implementations, the first removal operation may stop above the channel plug of channel structures 108 and 109.

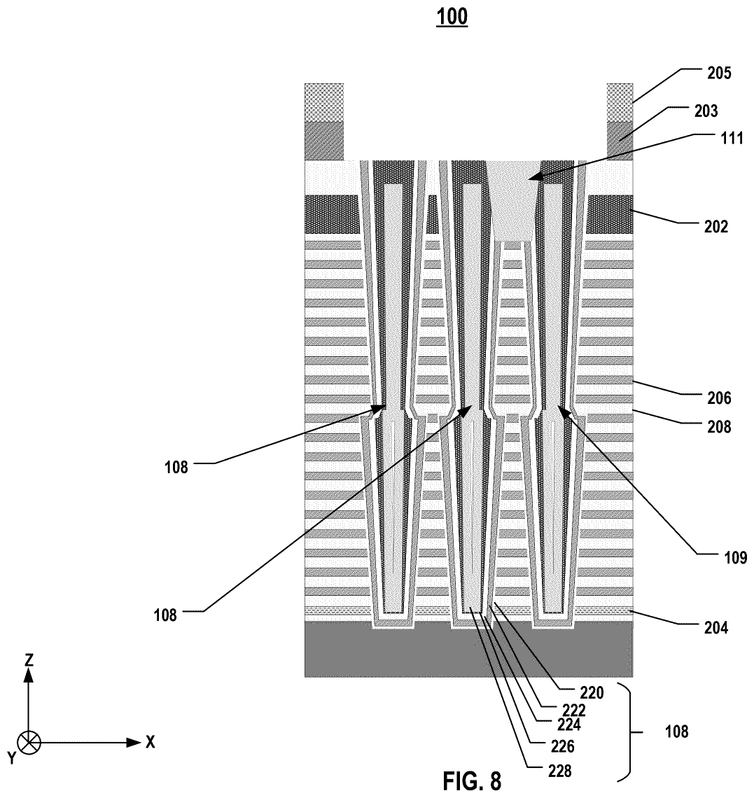

As shown in FIG. 9, a second removal operation, e.g., a dry etching process or a wet etching process, is performed to remove a portion of the dielectric layer above the select gate line 202. In some implementations, the second removal operation may remove the channel plug of channel structures 108 and 109 and stop above the select gate line 202.

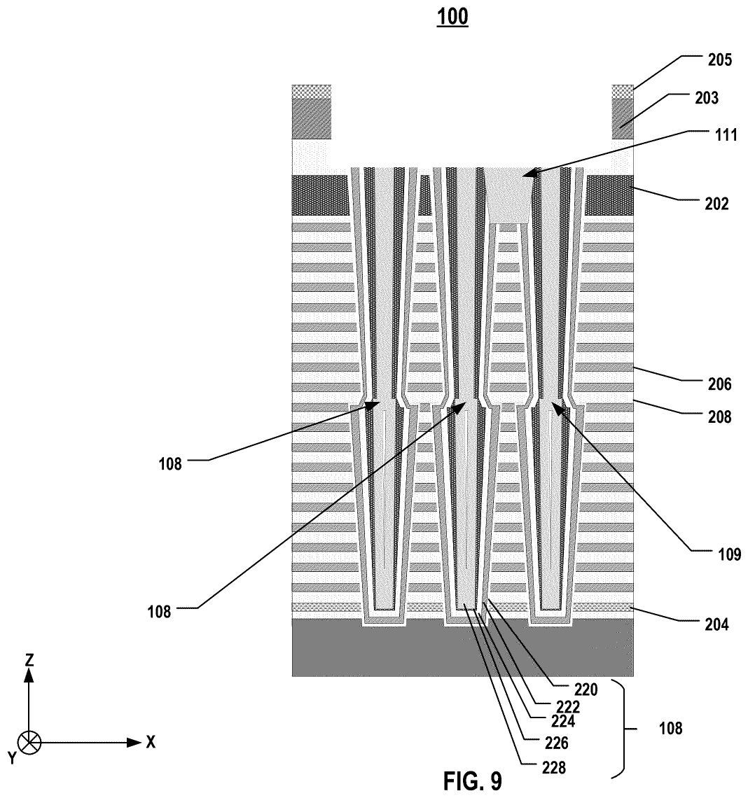

Then, as shown in FIG. 10, a third removal operation, e.g., a dry etching process or a wet etching process, is performed to remove the trench structure 111 and a portion of the capping layer 228. In some implementations, the trench structure 111 and the capping layer 228 are formed by the same dielectric material and can be removed in the same removal operation.

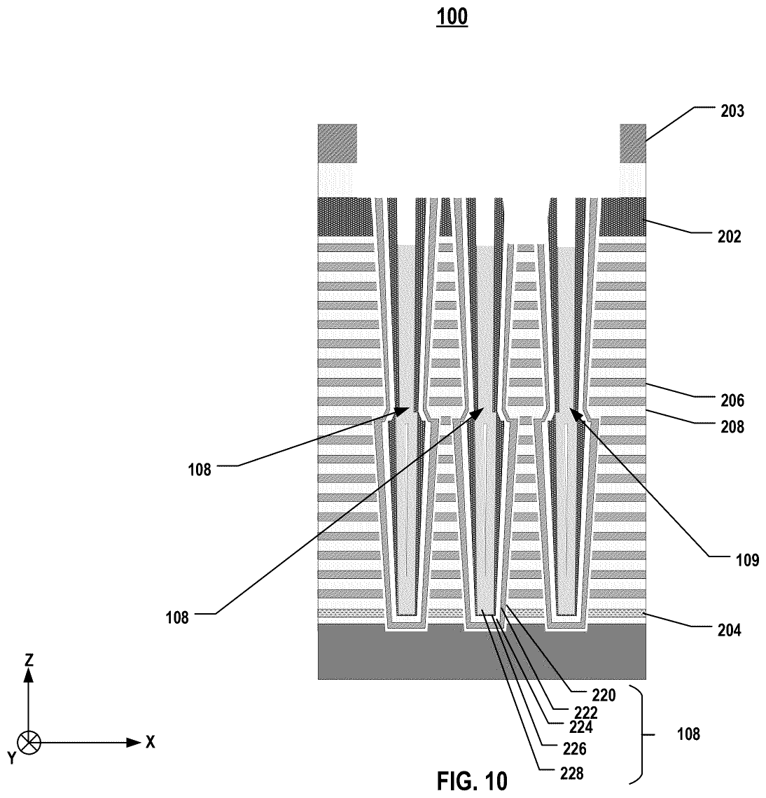

As shown in FIG. 11, a fourth removal operation, e.g., a dry etching process or a wet etching process, is performed to remove a portion of the semiconductor channel layer 226. In some implementations, the semiconductor channel layer 226 is formed by polysilicon, and the select gate line 202 is also formed by polysilicon. However, the select gate line 202 and the semiconductor channel layer 226 may have different etching rates in the same etching process, and therefore, the fourth removal operation can remove only the semiconductor channel layer 226 without damaging or lightly damaging the select gate line 202. In some implementations, the select gate line 202 and the semiconductor channel layer 226 may include the polysilicon layers having different doping types, different doping materials, and/or different doping concentrations, so that the select gate line 202 and the semiconductor channel layer 226 may have different etching rates in the same etching process. In some implementations, in the fourth removal operation, the etching rate of the polysilicon layer of the semiconductor channel layer 226 is greater than the etching rate of the polysilicon layer of the select gate line 202 in the removal operation.

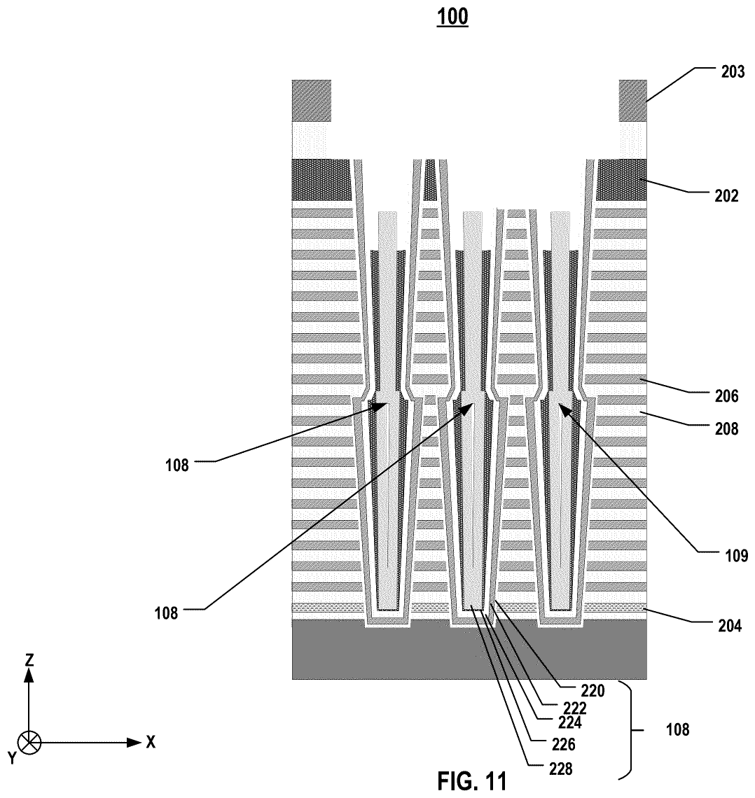

As shown in FIG. 12 and operation 1410 in FIG. 14, the dielectric layer 210 is formed on the top portion of the channel structures 108 and 109. In some implementations, the dielectric layer 210 covers the semiconductor channel, including the channel structures 108 and 109, and the select gate line 202. In some implementations, the bottom surface of the dielectric layer 210 is lower than the bottom surface of the select gate line 202 in a side view of the memory device 100. In some implementations, the top surface of the semiconductor channel, including the semiconductor channel layer 226 and the capping layer 228, is lower than the bottom surface of the select gate line 202 in the side view of the memory device 100.

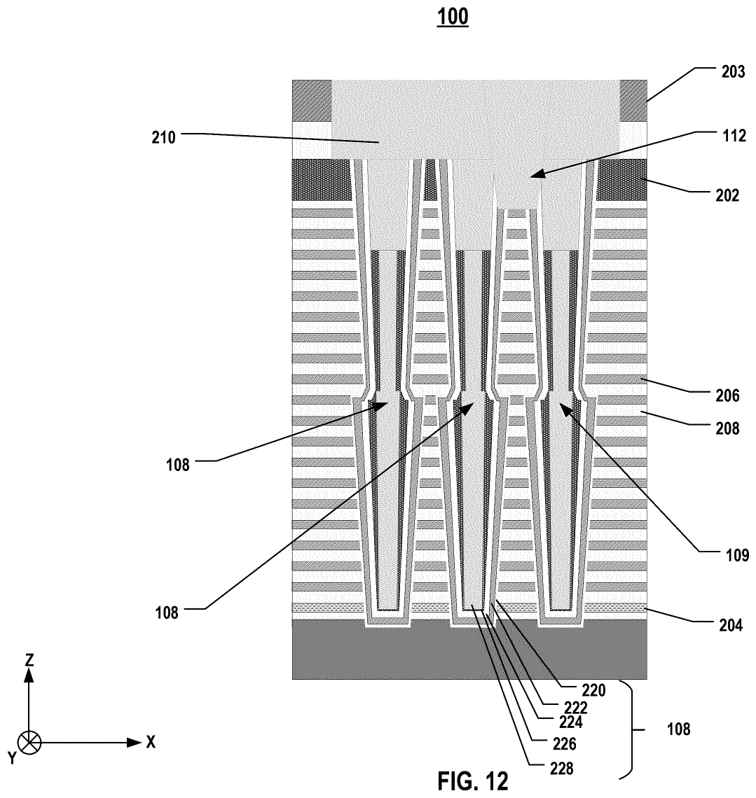

As shown in FIG. 13 and operation 1412 in FIG. 14, the conductive layer 110 is formed in the dielectric layer 210 in contact with the select gate line 202. Conductive layer 110 can be connected to the pick-up circuit to achieve the TSG pick-up design.

By using the structures of the memory devices and methods of forming the memory devices, the channel structures in the pick-up region and the core region can be designed the same to reduce the etching difficulty. At the same time, the present disclosure also forms the TSG pick-up by performing the photolithography, etching, and deposition operations after forming the channels to realize the TSG pick-up design.

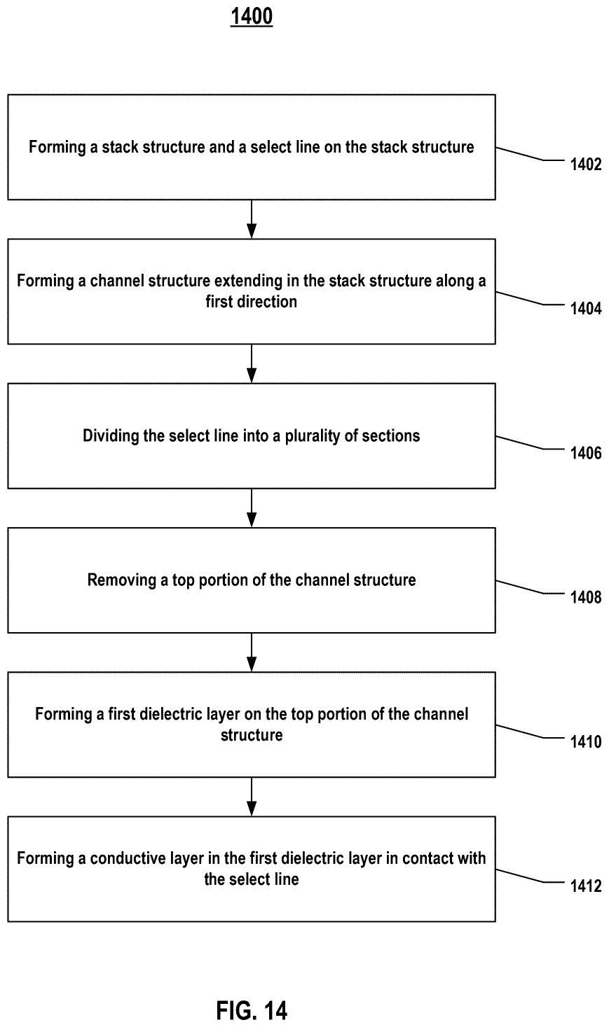

FIG. 15 illustrates a block diagram of a system 1500 having a memory device, according to some aspects of the present disclosure. System 1500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 15, system 1500 can include a host 1508 and a memory system 1502 having one or more memory devices 1504 and a memory controller 1506. Host 1508 can be a processor of an electronic device, such as a central processing unit (CPU), or a system-on-chip (SoC), such as an application processor (AP). Host 1508 can be configured to send or receive the data to or from memory device 1504.

Memory controller 1506 is coupled to memory device 1504 and host 1508 and is configured to control memory device 1504, according to some implementations. In some implementations, memory device 1504 can be the memory device 100 in FIGS. 1-13. Memory controller 1506 can manage the data stored in memory device 1504 and communicate with host 1508. In some implementations, memory controller 1506 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1506 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1506 can be configured to control operations of memory device 1504, such as read, erase, and program operations. In some implementations, memory controller 1506 is configured to control the array of memory cells through the first peripheral circuit and the second peripheral circuit. Memory controller 1506 can also be configured to manage various functions with respect to the data stored or to be stored in memory device 1504 including, but not limited to bad-block management, garbage collection, logical-to-physical address conversion, wear leveling, etc. In some implementations, memory controller 1506 is further configured to process error correction codes (ECCs) with respect to the data read from or written to memory device 1504. Any other suitable functions may be performed by memory controller 1506 as well, for example, formatting memory device 1504. Memory controller 1506 can communicate with an external device (e.g., host 1508) according to a particular communication protocol. For example, memory controller 1506 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

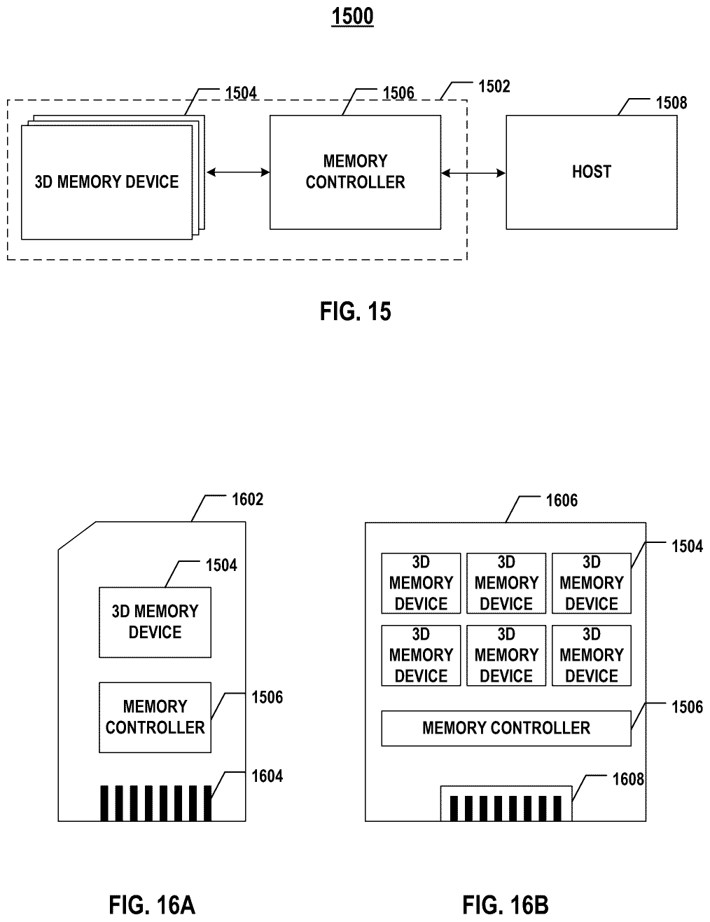

Memory controller 1506 and one or more memory devices 1504 can be integrated into various types of storage devices, for example, be included in the same package, such as a universal Flash storage (UFS) package or an eMMC package. That is, memory system 1502 can be implemented and packaged into different types of end electronic products. In one example as shown in FIG. 16A, memory controller 1506 and a single memory device 1504 may be integrated into a memory card 1602. Memory card 1602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1602 can further include a memory card connector 1604 coupling memory card 1602 with a host (e.g., host 1508 in FIG. 15). In another example as shown in FIG. 16B, memory controller 1506 and multiple memory devices 1504 may be integrated into an SSD 1606. SSD 1606 can further include an SSD connector 1608 coupling SSD 1606 with a host (e.g., host 1508 in FIG. 15). In some implementations, the storage capacity and/or the operation speed of SSD 1606 is greater than those of memory card 1602.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a stack structure comprising a plurality of gate lines and a select gate line;
a first channel structure extending through the plurality of gate lines along a first direction;
a dielectric layer disposed on the first channel structure and the select gate line, and extending along a second direction perpendicular to the first direction; and
a conductive layer disposed in the dielectric layer, and the conductive layer in contact with the select gate line.

2. The memory device of claim 1, wherein a top portion of the first channel structure is filled with the dielectric layer.

3. The memory device of claim 1, wherein a first bottom surface of the dielectric layer is lower than a second bottom surface of the select gate line in a side view of the memory device.

4. The memory device of claim 3, wherein the first channel structure comprises a blocking layer, a storage layer, a tunneling layer, a semiconductor channel layer, and a capping layer stacking along the second direction, and a first top surface of the semiconductor channel layer is lower than the second bottom surface of the select gate line in the side view of the memory device.

5. The memory device of claim 1, wherein the dielectric layer covers at least one first channel structure.

6. The memory device of claim 1, further comprising:
an isolation structure dividing the select gate line into a plurality of sections.

7. The memory device of claim 6, wherein the isolation structure extends along the first direction and a third direction perpendicular to the first direction and the second direction.

8. The memory device of claim 6, wherein the isolation structure is disposed in the dielectric layer.

9. The memory device of claim 6, wherein the isolation structure is disposed between the first channel structure and an adjacent channel structure.

10. The memory device of claim 9, wherein the first channel structure or the adjacent channel structure comprises a blocking layer, a storage layer, a tunneling layer, a semiconductor channel layer, and a capping layer stacking along the second direction, and a portion of the storage layer of the first channel structure or the adjacent channel structure is covered by the isolation structure.

11. The memory device of claim 10, wherein a second top surface of the portion of the storage layer covered by the isolation structure is lower than the select gate line in a side view of the memory device.

12. The memory device of claim 1, wherein a first thickness of the select gate line is greater than a second thickness of each of the plurality of gate lines.

13. The memory device of claim 1, wherein the select gate line is formed by a semiconductor material.

14. The memory device of claim 1, wherein
the memory device comprises a core region and a pick-up region;
a plurality of first channel structures, the dielectric layer, and the conductive layer are disposed in the pick-up region; and
a plurality of second channel structures are disposed in the core region.

15. The memory device of claim 14, wherein a first arrangement of the plurality of first channel structures in the pick-up region in a plan view of the memory device is the same as a second arrangement of the plurality of second channel structures in the core region in the plan view of the memory device.

16. A memory device, comprising:
a stack structure comprising a plurality of gate lines and a select gate line; and
a channel structure extending through the plurality of gate lines along a first direction,
wherein the channel structure comprises a semiconductor channel and a memory film disposed over the semiconductor channel, and a first top surface of the semiconductor channel is lower than a second top surface of the select gate line in a side view of the memory device.

17. The memory device of claim 16, wherein the memory film comprises a tunneling layer over the semiconductor channel, a storage layer over the tunneling layer, and a blocking layer over the storage layer, and the first top surface of the semiconductor channel is lower than a third top surface of the memory film in the side view of the memory device.

18. The memory device of claim 16, wherein the first top surface of the semiconductor channel is lower than a bottom surface of the select gate line in the side view of the memory device.

19. The memory device of claim 16, further comprising:
a dielectric layer disposed on the channel structure and the select gate line, and extending along a second direction perpendicular to the first direction; and
a conductive layer disposed in the dielectric layer, and the conductive layer in contact with the select gate line.

20. A method of forming a memory device, comprising:
forming a stack structure and a select gate line on the stack structure;
forming a channel structure extending in the stack structure along a first direction;
dividing the select gate line into a plurality of sections;
removing a top portion of the channel structure;
forming a first dielectric layer on the top portion of the channel structure; and
forming a conductive layer in the first dielectric layer in contact with the select gate line.
